(19) United States
(12) Patent Application Publication
(10) Pub. No.: US 2022/0045133 A1
(43) Pub. Date: Feb. 10, 2022

(54) DISPLAY PANEL AND DISPLAY DEVICE

(71) Applicant: JOLED INC., Tokyo (JP)

(72) Inventor: Toshihiro FUKUDA, Tokyo (JP)

(73) Assignee: JOLED INC., Tokyo (JP)

(21) Appl. No.: 17/392,272

(22) Filed: Aug. 3, 2021

(30) Foreign Application Priority Data
Aug. 5, 2020 (JP) 2020-132996
Jul. 20, 2021 (JP) 2021-119286

(51) Int. Cl. H01L 27/32; H01L 51/52

(52) U.S. Cl. CPC H01L 27/322; H01L 51/5271; H01L 51/5265; H01L 27/3211

(57) ABSTRACT

A display panel including pixels each including a self-luminous element and a color filter, including a green light emitting element among the self-luminous elements. The green light emitting element has an optical resonator structure in which a light transmissive metal thin film electrode, a green light emitting layer, and a light reflective electrode are disposed in this order with the light transmissive metal thin film electrode closest to one of the color filters corresponding to the green light emitting element, in order to enhance light intensity of a first wavelength, and the one of the color filters has a light transmittance of 50% or less for light having a second wavelength that is longer than the first wavelength and has a higher visibility characteristic as a green color component than the first wavelength.

This application claims priority to Japanese Patent Application No. 2020-132996 filed Aug. 5, 2020 and Japanese Patent Application No. 2021-119286 filed Jul. 20, 2021, the contents of which are hereby incorporated by reference in their entirety.

### BACKGROUND

### Technical Field

The present disclosure relates to display panels that include light emitting elements utilizing electroluminescence or a quantum dot effect, and display devices incorporating such display panels.

### Description of Related Art

In recent years, display devices using light emitting elements such as organic electroluminescence (EL) elements that utilize organic material electroluminescence or quantum light emitting diodes (QLED) that utilize quantum dot effects are becoming widespread. Each light emitting element has a basic structure in which a light emitting layer is disposed between a pair of electrodes, and when a voltage is applied between the electrodes, holes and electrons are recombined and the light emitting layer emits light.

A top-emission light emitting element that emits light “upwards” from a substrate has a light reflective electrode disposed nearer the substrate and a light transmissive electrode disposed farther from the substrate. A portion of light generated in the light emitting layer is transmitted directly through the light transmissive electrode and emitted and a portion is reflected by the light reflective electrode or the light transmissive electrode and propagates through the light emitting element before being emitted. As a technique for improving light extraction efficiency, a resonator structure is used in which an optical path length in the light emitting element is designed so that light is intensified by interference.

In a display panel for a color display, such a light emitting element forms a red (R), green (G), or blue (B) color sub-pixel, and adjacent RGB sub-pixels combine to form a pixel in a color display. Typically, a display panel incorporating a light emitting element uses a structure that suppresses reflection of external light in order to suppress deterioration of visibility caused by external light reflecting from reflective electrodes provided for each pixel (for examples, refer to JP 2018-32016 A, JP 2012-185992 A, and JP 2014-183024 A). Further, as a technique for improving color purity, for example, a structure included a combination of a resonator and a color filter is used (for example, refer to WO 2001/39554).

### SUMMARY

A display panel pertaining to an aspect of the present disclosure is a display panel including pixels each including a self-luminous element and a color filter, the display panel comprising a green light emitting element among the self-luminous elements. The green light emitting element has an optical resonator structure in which a light transmissive metal thin film electrode, a green light emitting layer, and a light reflective electrode are disposed in this order with the light transmissive metal thin film electrode closest to one of the color filters corresponding to the green light emitting element, in order to enhance light intensity of a first wavelength, and the one of the color filters has a light transmittance of 50% or less for light having a second wavelength that is longer than the first wavelength and has a higher visibility characteristic as a green color component than the first wavelength.

### BRIEF DESCRIPTION OF DRAWINGS

FIG. 1 is a cross-section diagram schematically illustrating structure of an organic EL display panel according to at least one embodiment of the present disclosure.

FIG. 2 is a cross-section diagram schematically illustrating light interference in a resonator structure formed in an organic EL element 1.

FIG. 3A is a graph illustrating an emission spectrum of an organic EL element 1(G) and a transmission spectrum of a conventional color filter (G). FIG. 3B is a graph illustrating Y value of the International Commission on Illumination (CIE) color matching function. FIG. 3C is a graph illustrating an external light reflection property of an organic EL element (G) provided with an optical resonator structure.

FIG. 4A is a graph illustrating a spectrum of reflected light when external light corresponding to a C light source is incident on an organic EL element (G) provided with an optical resonator structure. FIG. 4B is a graph illustrating a transmission spectrum of a color filter (G) according to Embodiments 1 and 2 and a reference example.

FIG. 5A is a graph illustrating a spectrum of reflected light from a sub-pixel 2(G). FIG. 5B is a graph illustrating a relationship between 565 nm transmittance of a color filter (G) and light reflectance of the sub-pixel 2(G).

FIG. 6 is a flowchart illustrating a manufacturing process of a display panel according to at least one embodiment of the present disclosure.

FIG. 7A, 7B, 7C, 7D, 7E are cross-section diagrams schematically illustrating part of a manufacturing process of a display panel according to at least one embodiment of the present disclosure. FIG. 7A illustrates a state in which a thin-film transistor (TFT) layer is formed on a substrate. FIG. 7B illustrates a state in which an interlayer insulating layer is formed on a substrate. FIG. 7C illustrates a state in which a pixel electrode material is formed on the interlayer insulating layer. FIG. 7D illustrates a state in which pixel electrodes are formed. FIG. 7E illustrates a state in which a bank material layer is formed on the interlayer insulating layer and the pixel electrodes.

FIGS. 8A, 8B, 8C, 8D are cross-section diagrams schematically illustrating part of the manufacturing process of the display panel according to at least one embodiment of the present disclosure. FIG. 8A illustrates a state in which banks are formed. FIG. 8B illustrates a state in which hole injection layers are formed on the pixel electrodes. FIG. 8C illustrates a state in which hole transport layers are formed on the hole injection layers. FIG. 7D illustrates a state in which light emitting layers are formed.

FIGS. 9A, 9B, 9C, 9D are cross-section diagrams schematically illustrating part of the manufacturing process of the display panel according to at least one embodiment of the present disclosure. FIG. 9A illustrates a state in which an intermediate layer is formed on the light emitting layers and the banks. FIG. 9B illustrates a state in which an electron transport layer is formed on the intermediate layer. FIG. 9C illustrates a state in which a counter electrode is formed on the electron transport layer. FIG. 9D illustrates a state in which a sealing layer is formed on the counter electrode.

FIGS. 10A, 10B, 10C, 10D are cross-section diagrams schematically illustrating part of the manufacturing process of the display panel according to at least one embodiment of the present disclosure. FIG. 10A illustrates a state in which a light-shielding material film is formed on an upper substrate. FIG. 10B illustrates a state in which a light-shielding film is formed on the upper substrate. FIG. 10C illustrates a state in which color filters are formed on the upper substrate. FIG. 10D illustrates a state in which a color filter substrate is attached to a light emitting element substrate.

FIG. 11 is a block diagram illustrating a structure of a display device according to at least one embodiment of the present disclosure.

### DETAILED DESCRIPTION

### Background to Aspect of Present Disclosure

According to a structure described in WO 2001/39554, light intensity at a peak wavelength and nearby wavelengths of light extracted from a light emitting element are controlled to improve color purity. However, according to the structure described in WO 2001/39554, color purity may decrease if a wavelength to which human visual sensitivity is high is among wavelengths that are not near the peak wavelength of light extracted from the light emitting element. The following describes this in more detail.

It is a known problem that in a display panel provided with light emitting elements, contrast and reflection problems can occur due to reflection of external light by electrodes. Therefore, for example, a technique exists for suppressing external light reflection using a circularly polarizing plate, or as described in WO 2001/39554, a technique exists for suppressing external light reflection using a color filter layer provided with a black matrix. However, a circularly polarizing plate absorbs light and a black matrix lowers an aperture ratio of a display panel and therefore either case can cause a reduction in luminous efficiency, an increase in power consumption, and shortened panel life.

On the other hand, as described in WO 2001/39554, a technique for suppressing external light reflection using an optical resonator structure is also known. As illustrated in the schematic cross-section diagram of FIG. 2, optical distance in an optical resonator structure is adjusted so that, for example, light travelling a path C₁ and light travelling a path C₂ intensify each other, where the path C₁ is from a light emission center to being directly emitted and the path C₂ is from a light emission center to being reflected at both a light transmissive electrode and a light reflective electrode before being emitted. The optical resonator structure functions as a filter that increases transmittance of external light having the same wavelength as extracted light, and therefore also functions as a structure to reduce reflectance of light having the same wavelength as extracted light and suppress contrast reduction of external light. Therefore, according to this structure, contrast can be improved and light purity can be increased in the wavelength of extracted light and nearby wavelength range. However, an optical resonator structure has no effect on wavelengths that are outside the wavelength of extracted light and nearby wavelength range. Therefore, if there is a wavelength to which human visual sensitivity is high in a wavelength range outside the wavelengths in the vicinity of extracted light, there may be a problem that color purity is not sufficiently high because the optical resonator structure does not function as a structure for suppressing external light reflection of such a wavelength. In particular, in a color panel using three RGB colors, a peak wavelength of a green (G) light emitting element is about 530 nm, but peak wavelength of M pyramidal cells (Y value in the CIE color function) is around 555 nm, and therefore the color purity of the green light emitting element can easily decrease.

In view of the above problems, the inventor has studied a structure for improving color purity by using a combination of an optical resonator structure and a color filter that does not adversely affect aperture ratio and luminance efficiency, and arrived at the present disclosure.

That is, an object of the present disclosure is to provide a display panel that improves color purity by using a combination of an optical resonator structure and a color filter that does not adversely affect aperture ratio and luminance efficiency.

### Aspects of Disclosure

A display panel pertaining to an aspect of the present disclosure is a display panel including pixels each including a self-luminous element and a color filter, the display panel comprising a green light emitting element among the self-luminous elements. The green light emitting element has an optical resonator structure in which a light transmissive metal thin film electrode, a green light emitting layer, and a light reflective electrode are disposed in this order with the light transmissive metal thin film electrode closest to one of the color filters corresponding to the green light emitting element, in order to enhance light intensity of a first wavelength, and the one of the color filters has a light transmittance of 50% or less for light having a second wavelength that is longer than the first wavelength and has a higher visibility characteristic as a green color component than the first wavelength.

According to the above aspect of the display panel, reflectance of light having the second wavelength can be suppressed for a pixel provided with the green light emitting layer. In a pixel that includes the green light emitting layer, light having the first wavelength, which is the desired light, is efficiently emitted, and a decrease in color purity can be suppressed, where the decrease in color purity is caused by light having a second wavelength, which has high visibility characteristics and is included in external reflected light.

Further, the display panel according to the above aspect may be as follows.

According to at least one embodiment, in the International Commission on Illumination (CIE) color matching functions, a Y value corresponding to the second wavelength is larger than a Y value corresponding to the first wavelength.

According to the above embodiment, it is possible to suppress the influence of reflected external light of the second wavelength, which is easier to see than light of the first wavelength but has low color purity.

According to at least one embodiment, the first wavelength is 530 nm or less and the second wavelength is from 545 nm to 565 nm. Further, the second wavelength may be a wavelength selected from wavelengths in the range from 545 nm to 565 nm. According to at least one embodiment, the first wavelength is 530 nm or less and the second wavelength is 565 nm. According to at least one embodiment, the first wavelength is 530 nm or less and the second wavelength is 555 nm. According to at least one embodiment, the first wavelength is 530 nm or less and the second wavelength is 545 nm.

According to the above embodiments, contrast of pixels is improved and color purity can be increased by using green light having a high color purity at the first wavelength and suppressing reflection of light having the second wavelength, which is highly visible and has a low color purity.

According to at least one embodiment, the one of the color filters has a light transmittance of 70% or more for light having the first wavelength.

According to the above embodiment, light extraction efficiency can be improved without lowering luminance of light having the first wavelength, and color purity can also be improved.

According to the above embodiment, an aperture ratio of a pixel including the green light emitting element is 50% or more.

According to the above embodiment, life of the display panel can be extended.

A display panel pertaining to an aspect of the present disclosure is a display panel including pixels each including a self-luminous element and a color filter, the display panel comprising a green light emitting element among the self-luminous elements. The green light emitting element has an optical resonator structure in which a light transmissive metal thin film electrode, a green light emitting layer, and a light reflective electrode are disposed in this order with the light transmissive metal thin film electrode closest to one of the color filters corresponding to the green light emitting element, in order to enhance light intensity of a first wavelength, and a pixel including the green light emitting element is further provided with a second color filter that has a light transmittance of 50% or less for light having a second wavelength that is longer than the first wavelength and has a higher visibility characteristic as a green color component than the first wavelength.

According to the above aspect of the display panel, reflectance of light having the second wavelength can be suppressed for a pixel provided with the green light emitting layer. In a pixel that includes the green light emitting layer, light having the first wavelength, which is the desired light, is efficiently emitted, and a decrease in color purity can be suppressed, where the decrease in color purity is caused by light having a second wavelength, which has high visibility characteristics and is included in external reflected light.

A display device pertaining to an aspect of the present disclosure is a display device including a display panel pertaining to an aspect of the present disclosure and a drive circuit.

According to the above aspect, a display device can be implemented having the same effects as the display panel according to one aspect of the present disclosure.

A display panel manufacturing method pertaining to an aspect of the present disclosure is a display panel manufacturing method comprising: forming light reflective electrodes on a substrate; forming a light emitting layer above each of the light reflective electrodes; forming a light transmissive metal thin film electrode above the light emitting layers to form an optical resonator structure; and forming a color filter above each of the light emitting layers, above the light transmissive metal thin film electrode, wherein in forming the light emitting layers, at least one light emitting layer is a green light emitting layer, and in forming the color filters, when a peak wavelength of the optical resonator structure is a first wavelength, light transmittance of a color filter above the green light emitting layer is 50% or less for light having a second wavelength that is longer than the first wavelength and has a higher visibility characteristic as a green color component than the first wavelength.

According to the display panel manufactured by the above aspect of the display panel manufacturing method, reflectance of light having the second wavelength can be suppressed for a pixel provided with the green light emitting layer. In a pixel that includes the green light emitting layer, light having the first wavelength, which is the desired light, is efficiently emitted, and a decrease in color purity can be suppressed, where the decrease in color purity is caused by light having a second wavelength, which has high visibility characteristics and is included in external reflected light.

### Embodiments

The following describes an embodiment of a display panel according to the present disclosure. The following describes an embodiment that is illustrative of structure, action, and effect according to one aspect of the present disclosure, and aside from essential features, the present disclosure is not limited to the embodiment described. Further, in the following specification and claims, on, above, up, upwards, and upper indicate positional relationships relative to a light emission direction and not necessarily an absolute vertical direction. Further, in the scope of the following specification and claims, the character “˜” is used to indicated a numerical range that includes the values at both ends of the numerical range.

### 1. Display Panel Structural Outline

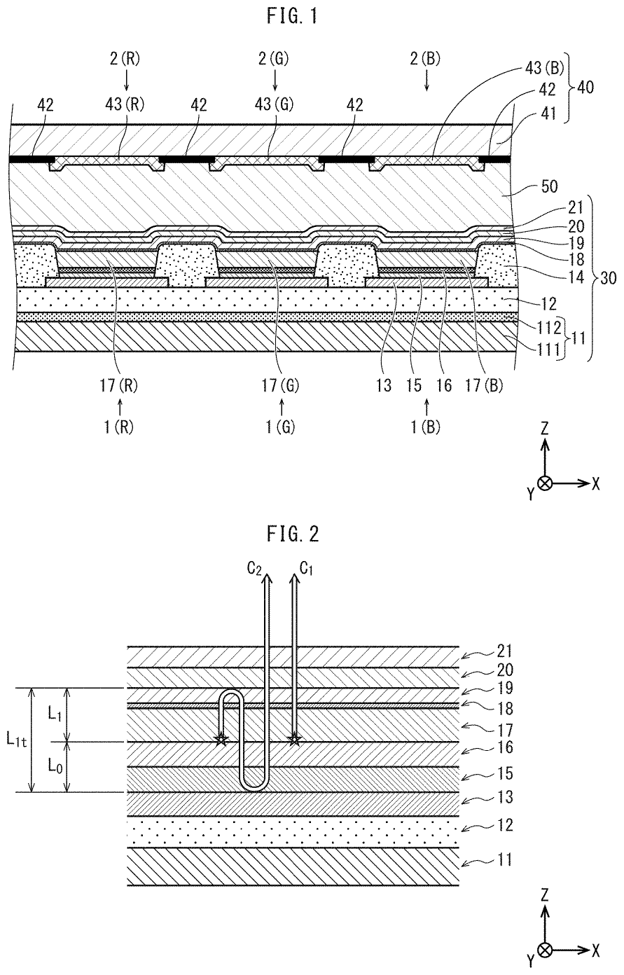

FIG. 1 is a cross-section diagram of an organic EL display panel 100 (see

FIG. 11) as display panel according to at least one embodiment. The organic EL display panel 100 includes a plurality of pixels each composed of sub-pixels 2(R), 2(G), 2(B) that each emit light of a corresponding color (red, green, blue). The organic EL display panel 100 includes a light emitting element substrate 30 including organic EL elements 1(R), 1(G), 1(B) as light emitting elements and a color filter substrate 40 including color filters and a black matrix. A combination of one of the organic EL elements 1(R) with a color filter 43(R) constitutes one of the sub-pixels 2(R), a combination of one of the organic EL elements 1(G) with a color filter 43(G) constitutes one of the sub-pixels 2(G), and a combination of one of the organic EL elements 1(B) with a color filter 43(B) constitutes one of the sub-pixels 2(B). FIG. 1 illustrates a cross-section of one pixel composed of one each of the sub-pixels 2(R), 2(G), 2(B).

In the organic EL display panel 100, each of the organic EL elements 1 is a top emission type that emits light forward (upwards in a z-axis direction of FIG. 1).

The organic EL elements 1(R), the organic EL elements 1(G), and the organic EL elements 1(B) all have almost the same structure, and therefore are described as an organic EL element 1 when not distinguished.

### 2. Display Panel Structural Details

### (2.1) Structure of Light Emitting Element Substrate 30

As illustrated in FIG. 1, the organic EL element 1 includes a substrate 11, an interlayer insulating layer 12, a pixel electrode 13, banks 14, a hole injection layer 15, a hole transport layer 16, a light emitting layer 17, an intermediate layer 18, an electron injection transport layer 19, a counter electrode 20, and a sealing layer 21. The pixel electrode 13 and the counter electrode 20 correspond to a light reflective electrode and a light transmissive electrode of the present disclosure, respectively.

The substrate 11, the interlayer insulating layer 12, the intermediate layer 18, the electron injection transport layer 19, the counter electrode 20, and the sealing layer 21 are not specific to each pixel and are common to a plurality of the organic EL elements 1 of the light emitting element substrate 30.

### <Substrate>

The substrate 11 includes a base 111 made of an insulative material and a thin film transistor (TFT) layer 112. A drive circuit is formed in the TFT layer 112 for each sub-pixel. The base 111 can be, for example, a glass substrate, a quartz substrate, a plastic substrate or the like. As a plastic material, a thermoplastic resin or a thermosetting resin may be used. For example, polyimide (PI), polyetherimide (PEI), polysulfone (PSu), polycarbonate (PC), polyethylene terephthalate (PET), polyethylene naphthalate (PEN), polybutylene terephthalate, a thermoplastic elastomer that is styrene-based, polyolefin-based, polyurethane-based, or the like, an epoxy resin, unsaturated polyester, silicone resin, polyurethane, or the like, or a copolymer, blend, polymer alloy, or the like that is mainly composed of one or more of the above. From these, selection for durability with respect to processing temperature can be made, and one or more types may be selected for use in a laminate of laminated layers.

### <Interlayer Insulating Layer>

The interlayer insulating layer 12 is formed on the substrate 11. The interlayer insulating layer 12 is made of a resin material and is for planarizing an uneven upper surface of the TFT layer 112. An example of the resin material is a positive type photosensitive material. Examples of such photosensitive material include an acrylic resin, a polyimide resin, a siloxane resin, a phenol resin, or the like. Further, although not illustrated in the cross-section of FIG. 1, a contact hole is formed in the interlayer insulating layer 12 for each sub-pixel.

### <Pixel Electrodes>

The pixel electrodes 13 are formed on the interlayer insulating layer 12. The pixel electrodes 13 correspond one-to-one with pixels, and each is electrically connected to the TFT layer 112 through a contact hole provided in the interlayer insulating layer 12.

According to at least one embodiment, the pixel electrodes 13 function as light reflective anodes.

Specific examples of light reflective metal materials include silver (Ag), aluminum (Al), aluminum alloy, molybdenum (Mo), silver, palladium, copper alloy (APC), silver, rubidium, gold alloy (ARA), molybdenum chromium alloy (MoCr), molybdenum tungsten alloy (MoW), nickel chromium alloy (NiCr), or the like.

Each of the pixel electrodes 13 may be a single metal layer, or may be a laminated structure in which a layer made of a metal oxide such as indium tin oxide (ITO) or indium zinc oxide (IZO) is laminated on a metal layer.

### <Banks>

The banks 14 are formed on the pixel electrodes 13 such that for each of the pixel electrodes 13, a portion of an upper surface is exposed and a peripheral portion of the upper surface is covered. The portion of the upper surface of each of the pixel electrodes 13 that is not covered by the banks 14 (hereinafter also referred to as an “aperture”) corresponds to a sub-pixel. That is, the banks 14 have apertures 14a that correspond one-to-one with sub-pixels.

According to at least one embodiment, the banks 14 are formed on the interlayer insulating layer 12 where the pixel electrodes 13 are not present. That is, where the pixel electrodes 13 are not present, bottom faces of the banks 14 are in contact with an upper surface of the interlayer insulating layer 12.

The banks 14 may be made of an insulating organic material (for example, acrylic resin, polyimide resin, novolac resin, phenol resin, or the like). The banks 14 function as a structure for preventing applied ink from overflowing if the light emitting layers 17 are formed by an application method, and function as a structure for mounting a vapor deposition mask if the light emitting layers 17 are formed by a vapor deposition method. According to at least one embodiment, the banks 14 are made of a resin material, and examples of material of the banks 14 include acrylic resin, polyimide resin, siloxane resin, and phenol resin. According to at least one embodiment, phenol resin is used.

### <Hole Injection Layers>

The hole injection layers 15 are provided on the pixel electrodes 13 to promote injection of holes from the pixel electrodes 13 to the light emitting layers 17. Specific examples of material of the hole injection layers 15 include electrically conductive polymer materials such as poly(3,4-ethylenedioxythiophene) polystyrene sulfonate (PEDOT:PSS).

The hole injection layers 15 may be made of a transition metal oxide. Specific examples of transition metals include silver (Ag), molybdenum (Mo), chromium (Cr), vanadium (V), tungsten (W), nickel (Ni), and iridium (Ir). Transition metals can take a plurality of oxidation numbers, and therefore a plurality of energy levels, and as a result, hole injection is facilitated, which contributes to a reduction in drive voltage. In this case, the hole injection layers 15 preferably have a lame work function.

The hole injection layers 15 may each have a laminated structure in which an electrically conductive polymer material is laminated on a transition metal oxide.

### <Hole Transport Layers>

The hole transport layers 16 have a function of transporting holes injected from the hole injection layers 15 to the light emitting layers 17, and are made of an organic material having high hole mobility in order to efficiently transport holes from the hole injection layers 15 to the light emitting layers 17. The hole transport layers 16 are formed by applying and drying an organic material solution. As an organic material of the hole transport layers 16, a polymer compound such as polyfluorene or a derivative thereof, or polyarylamine or a derivative thereof can be used.

Further, the hole transport layers 16 may be made of a triazole derivative, an oxadiazole derivative, an imidazole derivative, a polyarylalkane derivative, a pyrazoline derivative and pyrazolone derivative, a phenylenediamine derivative, an arylamine derivative, an amino-substituted chalcone derivative, an oxazole derivative, a styrylanthracene derivative, a fluorenone derivative, a hydrazone derivative, a stilbene derivative, a porphyrin compound, an aromatic tertiary amine compound and styrylamine compound, a butadiene compound, a polystyrene compound, a hydrazone derivative, a triphenylmethane derivative, or a tetraphenylbenzene derivative. More preferably, a porphyrin compound, an aromatic tertiary amine compound, a styrylamine compound, or the like may be used. In such a case, the hole transport layers 16 are formed by a vacuum deposition. Materials and manufacturing methods of the hole transport layers 16 are not limited to those described above, any material having a hole transport function may be used, and any manufacturing method that can be used for manufacturing the hole transport layers 16 may be used.

### <Light Emitting Layers>

The light emitting layers 17 are formed in the apertures 14a. The light emitting layers 17 have a function of emitting light of a corresponding color R, G, or B, by recombination of holes and electrons. As materials of the light emitting layers 17, known materials can be used.

If the light emitting element 1 is an organic EL element, examples of an organic light emitting material contained in the light emitting layers 17 can be a fluorescent substance such as an oxinoid compound, a perylene compound, a coumarin compound, an azacoumarin compound, an oxazole compound, an oxadiazole compound, a perinone compound, a pyrrolopyrrole compound, a naphthalene compound, an anthracene compound, a fluorene compound, a fluoranthene compound, a tetracene compound, a pyrene compound, a coronene compound, a quinolone compound and an azaquinolone compound, a pyrazoline derivative and a pyrazolone derivative, a rhodamine compound, a chrysene compound, a phenanthrene compound, a cyclopentadiene compound, a stilbene compound, a diphenylquinone compound, a styryl compound, a butadiene compound, a dicyanomethylene compound, a dicyanomethylene thiopyran compound, a fluorescein compound, a pyrylium compound, a thiapyrylium compound, a selenapyrylium compound, a telluropyrylium compound, an aromatic aldadiene compound, an oligophenylene compound, a thioxanthene compound, a cyanin compound, an acridine compound, a metal complex of an 8-hydroxyquinolin compound, a metal complex of a 2-bipyridine compound, a complex of a Schiff base and a group III metal, a metal complex of oxine, a rare earth complex, or the like. Further, a known phosphorescent substance such as a phosphorescing metal complex such as tris(2-phenylpyridine) iridium can be used. Further, the light emitting layers 17 may be formed by using a polymer compound such as polyfluorene or a derivative thereof, polyphenylene or a derivative thereof, polyarylamine or a derivative thereof, or a mixture of a low molecular weight compound and such a polymer compound. The light emitting elements 1 may be inorganic EL elements, and inorganic light emitting materials can be used as materials of the light emitting layers 17. Further, the light emitting elements 1 may be quantum dot light emitting diodes (QLED), and materials having a quantum dot effect can be used as materials of the light emitting layers 17.

### <Intermediate Layer>

The intermediate layer 18 is formed on the light emitting layers 17 and includes a fluoride or quinolinium complex of a metal material that has an electron injection property. The metal material is selected from alkali metals or alkaline earth metals. Specific examples of alkali metals include lithium (Li), sodium (Na), potassium (K), rubidium (Rb), cesium (Cs), and francium (Fr). Specific examples of alkaline earth metals include calcium (Ca), strontium (Sr), barium (Ba), and radium (Ra). According to at least one embodiment, the intermediate layer 18 includes sodium fluoride (NaF).

### <Electron Injection Transport Layer>

The electron injection transport layer 19 is formed on the intermediate layer 18, and is made of an organic material having an electron transport property doped with a metal material for improving an electron injection property. Here, doping means that metal atoms or metal ions of the metal material are dispersed substantially evenly in the organic material, and more specifically indicates forming a single phase containing the organic material and a trace amount of the metal material. It is preferable that no other phase exists, and in particular that no phase exists composed of only the metal material such as a metal piece or metal film and no phase exists containing the metal material as a main component. Further, in a single phase containing the organic material and a trace amount of the metal material, concentration of metal atoms or metal ions is preferably uniform, and the metal atoms or metal ions are preferably not aggregated. As the metal material, selecting from rare earth metals is preferable, and ytterbium (Yb) is more preferable. According to at least one embodiment, Yb is selected. Further, the amount of the metal dopant in the electron injection transport layer 19 is preferably from 3 wt % to 60 wt %. According to at least one embodiment, 20 wt %.

An example of the organic material used for the electron injection transport layer 19 is a π electron low molecular weight organic material such as an oxadiazole derivative (OXD), a triazole derivative (TAZ), a phenanthroline derivative (BCP, Bphen), or the like.

### <Counter Electrode>

The counter electrode 20 is made of a light transmissive electrically conductive material, and is formed on the electron injection transport layer 19. According to at least one embodiment, the counter electrode functions as a cathode.

A light reflective interface between the counter electrode 20 and the electron injection transport layer 19 contributes to forming a resonator structure when paired with light reflective interfaces between the pixel electrodes 13 and the hole injection layers 15. Therefore, when light emitted from the light emitting layers 17 is incident on the counter electrode 20 from the electron injection transport layer 19, a portion of the light needs to be reflected back through the electron injection transport layer 19. Therefore, it is preferable that the counter electrode 20 and the electron injection transport layer 19 have different refractive indices. Accordingly, the counter electrode is preferably is metal thin film. In order to ensure light transmission, film thickness of the metal layer is from 1 nm to 50 nm.

Examples of material of the counter electrode 20 include Ag, a silver alloy containing Ag as a main component, Al, and an Al alloy containing Al as a main component. Examples of Ag alloys include magnesium-silver alloy (MgAg) and indium-silver alloy. Ag has a low resistivity, and Ag alloy is preferable in that it has excellent heat resistance and corrosion resistance and can maintain good electrical conductivity for a long period of time. Examples of Al alloy include magnesium-aluminum alloy (MgAl) and lithium-aluminum alloy (LiAl). Examples of other alloys include lithium-magnesium alloy and lithium-indium alloy. According to at least one embodiment, the counter electrode 20 is a thin film of Ag.

### <Sealing Layer>

The sealing layer 21 is made of a light transmissive material and is formed on the counter electrode 20.

The sealing layer 21 functions as a sealing layer that protects the light emitting layers 17, the intermediate layers 18, and the like from moisture and the like. Further, an interface between the counter electrode 20 and the sealing layer 21 may be paired with the reflective interfaces between the pixel electrodes 13 and the hole injection layers 15 to form a resonator structure. Examples of a material of the sealing layer 21 include silicon oxynitride (SiON) and silicon nitride (SiN). The sealing layer 21 may further contain a resin material such as an acrylic resin or a silicone resin.

### (2.2) Structure of Color Filter Substrate 40

As illustrated in FIG. 1, the color filter substrate 40 includes an upper substrate 41, a light shielding film 42, and color filters 43.

### <Upper Substrate>

The upper substrate 41 is a light transmissive substrate that holds the light shielding film 42 and the color filters 43. Further, the upper substrate 41 may have a function of improving rigidity of the organic EL display panel 100 and may have a function together with the sealing layer 21 of preventing intrusion of moisture, air, and the like. The upper substrate 41 can be, for example, a glass substrate, a quartz substrate, a plastic substrate or the like.

### <Light Shielding Film>

The light shielding film 42 is provided with apertures that correspond to the organic EL elements 1, as illustrated in FIG. 1, and blocks light at positions between adjacent organic EL elements 1. The light shielding film 42 is a black resin layer for preventing visible light having wavelengths corresponding to R, G, B from being transmitted, and is made of a resin material containing a black pigment, for example. As the resin material, an acrylic resin, a polyimide resin, a novolac resin, a phenol resin, or the like can be used. As the black pigment, a carbon black pigment, a titanium black pigment, a metal oxide pigment, or the like can be used.

### <Color Filter>

As illustrated in FIG. 1, the color filters 43 are provided in apertures of the light shielding film 42 to face the organic EL elements 1. The color filters 43 are light-transmissive layers used to transmit visible light having wavelengths corresponding to R, G, and B, and have a function to correct emitted light to improve contrast and color purity, where a color filter 43(R) corrects light emitted from an organic EL element 1(R), a color filter 43(G) corrects light emitted from an organic EL element 1(G), and a color filter 43(B) corrects light emitted from an organic EL element 1(B). The color filters 43 are made of, for example, a resin material containing dyes.

The color filters 43(G) have a transmittance of 70% or more at peak wavelength (around 520 nm) amplified in a resonator structure of the organic EL elements 1(G). Further, in a wavelength range from 545 nm to 565 nm, there is a wavelength having a transmittance of 50% or less. That is, a wavelength having a transmittance of 50% or less is a wavelength selected from a wavelength in a range from 545 nm to 565 nm and may be, for example, 565 nm, 555 nm, or 545 nm. More details are provided later.

### (2.3) Bonding Layer

The bonding layer 50 is a bonding layer for attaching the light emitting element substrate 30 to the color filter substrate 40 so that they face each other, and has a function of protecting the light emitting element substrate 30 and the color filter substrate 40 from moisture and air. The bonding layer 50 is made of a transmissive resin material such as an acrylic resin, a silicone resin, or an epoxy resin.

### 3. External Light Reflection Suppression Structure

### (3.1) Optical Resonator Structures

FIG. 2 is a diagram illustrating light interference in an optical resonator structure of the organic EL element 1 according to at least one embodiment. An optical resonator structure is formed from the interfaces between the pixel electrodes 13 and the hole injection layers 15 to the interface between the counter electrode 20 and the electron injection transport layer 19. A second optical resonator structure is formed from the interfaces between the pixel electrodes 13 and the hole injection layers 15 to an interface between a second optical adjustment layer 212 and a first optical adjustment layer 211. The light emitting layers 17 exist in the first optical resonator structure and the second optical resonator structure.

FIG. 2 illustrates main paths of light emitted from the light emitting layers 17. The path C₁ is a path where light emitted from the light emitting layers 17 towards the counter electrode 20 passes through the counter electrode 20 without being reflected. The path C₂ is a path where light emitted from the light emitting layers 17 towards the counter electrode 20 is reflected at the interface between the counter electrode 20 and the electron injection transport layer 19, is again reflected at one of the interfaces between the pixel electrodes 13 and the hole injection layers 15, then is transmitted through one of the light emitting layers 17 and the counter electrode 20. In this optical resonator structure, interference occurs between light emitted from the path C₁ and light emitted from the path C₂ to become light emitted from the light emitting elements 1.

A difference in optical distance between the path C₁ and the path C₂ corresponds to an optical film thickness L₁ₜ, which the sum of an optical film thickness L₀ and an optical film thickness L₁. Here, optical film thickness is a value obtained by integrating refractive indices with film thicknesses of films. More specifically, the optical film thickness L₁ₜ is a value obtained by summing the refractive index of the hole injection layers 15 multiplied by the film thickness of the hole injection layers 15, the refractive index of the hole transport layers 16 multiplied by the film thickness of the hole transport layers 16, the refractive index of the light emitting layers 17 multiplied by the film thickness of the light emitting layers 17, the refractive index of the intermediate layer 18 multiplied by the film thickness of the intermediate layer 18, and the refractive index of the electron injection transport layer 19 multiplied by the film thickness of the electron injection transport layer 19. Similarly, a difference in optical distance between the path C₁ and a path C₃ corresponds to an optical film thickness L₂ₜ, which the sum of an optical film thickness L₀ and an optical film thickness L₂.

In this optical resonator structure, the optical film thickness L₁ₜ is set so that light emitted from the path C₁ and light emitted from the path C₂ intensify each other.

In the organic EL element 1(G), for example, the optical film thickness L₁ₜ is set to intensify light having a wavelength of 520 nm. Further, similarly, in each of the organic EL elements 1(R) and the organic EL elements 1(B), the optical film thickness L₁ₜ is set to intensify light of a desired wavelength. An optical resonator structure can be said to be a filter having improved transmittance of light of a desired wavelength, and therefore with respect to external light, functions as a filter having high transmittance of light of a desired wavelength and in other words low reflectance of light of the desired wavelength.

### (3.2) External Light Reflection and Luminosity

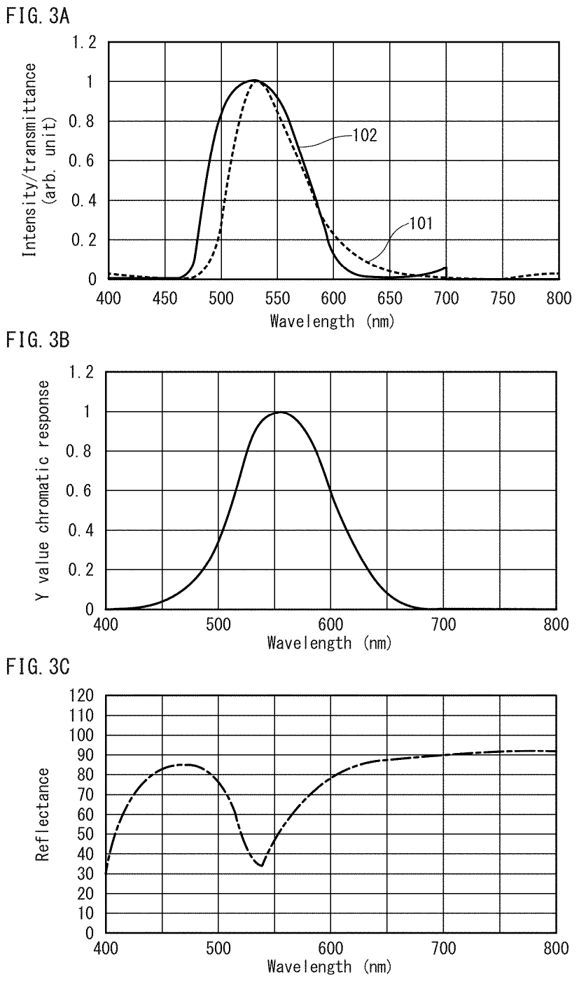

FIG. 3A is a graph illustrating an emission spectrum of an organic EL element 1(G) and a transmission spectrum of a reference example (conventional) color filter (G).

As illustrated by the emission spectrum 101 of FIG. 3A, the emission spectrum of the organic EL element 1(G) that has an optical resonator structure to enhance peak wavelength has a peak around a wavelength of 520 nm (approximately from 520 nm to 530 nm). On the other hand, the transmission spectrum 102 of the color filter (G) of the reference example is designed in order to improve color purity to so as not to transmit light having a shorter wavelength than about 460 nm or light having a longer wavelength than about 650 nm.

The profile of the Y value in the CIE color function indicating human visual sensitivity, particularly sensitivity of M pyramidal cells, becomes maximum around a wavelength of 555 nm, as illustrated in FIG. 3B. The peak wavelength of G having high color purity is from about 520 nm to 530 nm, and therefore reflected light having a wavelength of 540 nm or more, particularly reflected light having a wavelength of about 555 nm, causes a decrease in color purity of sub pixels. Here, intensity Y of reflected light is indicated as follows, using intensity I of light from an incident light source, an aperture A of a sub pixel, and reflectance R of the sub pixel.

Y=I×A×R Expression (1)

Here, the intensity I of light from the incident light source does not depend on the display panel structure, but when the aperture ratio A of the sub pixel 2 is decreased, current density to the organic EL element 1 increases, and this has an adverse effect on life of the organic EL element 1. There, in order to suppress reflection of external light without lowering luminance efficiency of the organic EL element 1, it is preferable to reduce the reflectance R of the sub pixel at the wavelength for which suppression of reflection of external light is desired.

Reflectance of a sub pixel of the display panel is indicated as follows, where T_{F} is light transmittance of a color filter of the sub pixel and R_{A} is light reflectance of the organic EL element having an optical resonator structure.

R=R_{A}×T_{F}² Expression (2)

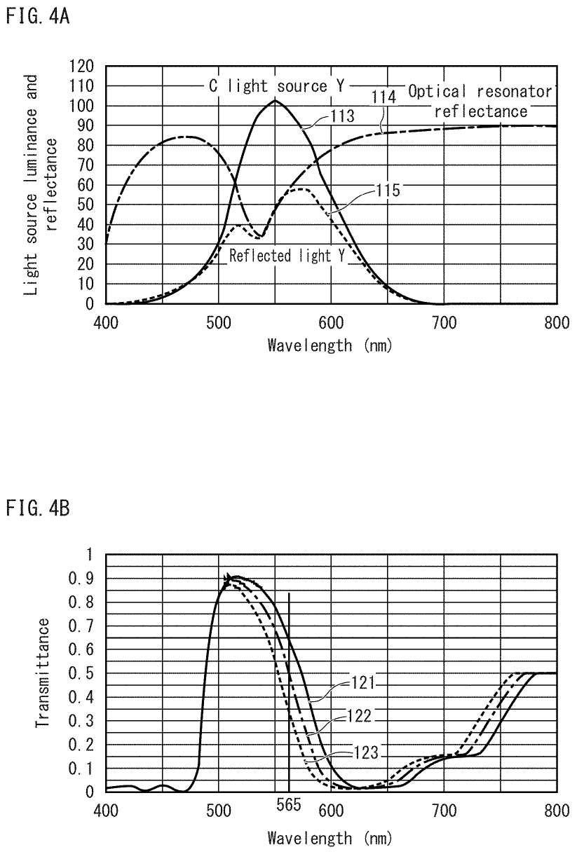

As described above, the optical resonator structure is designed so that the emission peak is around the wavelength of 520 nm, and therefore the reflectance R_{A} is low around 520 nm to 530 nm, as illustrated in FIG. 3C. Therefore, when an incident light source is C light source, then as illustrated in FIG. 4A, a reflected light spectrum 115 without a color is indicated by summing the incident light spectrum 113 and the reflected light spectrum 114 and peaks around a wavelength from 550 nm to 570 nm. As illustrated in FIG. 3B, light having a wavelength from 550 nm to 570 nm has a higher visibility property than light having a wavelength of about 520 nm, and therefore reflected light having a wavelength around 550 nm 570 nm causes a decrease in color purity of the sub pixel 2(G). That is, in the absence of a color filter, when external light is incident on the sub pixel 2(G) in a light emitting state, color purity of the sub pixel 2(G) is decreased.

### (3.3) Color Filter Properties

The following describes spectrums of reflected light when a color filter is present, comparing color filters according to at least one embodiment (Embodiment 1, Embodiment 2) to a conventional color filter (Reference Example).

FIG. 4B illustrates transmission spectra of color filters of Embodiment 1, Embodiment 2, and the Reference Example. In each of the color filters, transmittance at an extraction wavelength (around 520 nm to 530 nm) of the optical resonator structure of the organic EL element 1(G) is about 90%. On the other hand, transmittance around 565 nm, which is a CIE color matching function Y value peak wavelength, is 63% for a spectrum 121 of the Reference Example, 50% for a spectrum 122 of Embodiment 1, and 34% for a spectrum 123 of Embodiment 2. As described above, light passes through a color filter twice in a reflected light propagation path, and therefore a reflected light spectrum when a color filter is present, as indicated by Expression (2), is a value obtained by integrating the square of transmittance of the color filter with respect to the reflected light spectrum 115 when a color filter is not present.

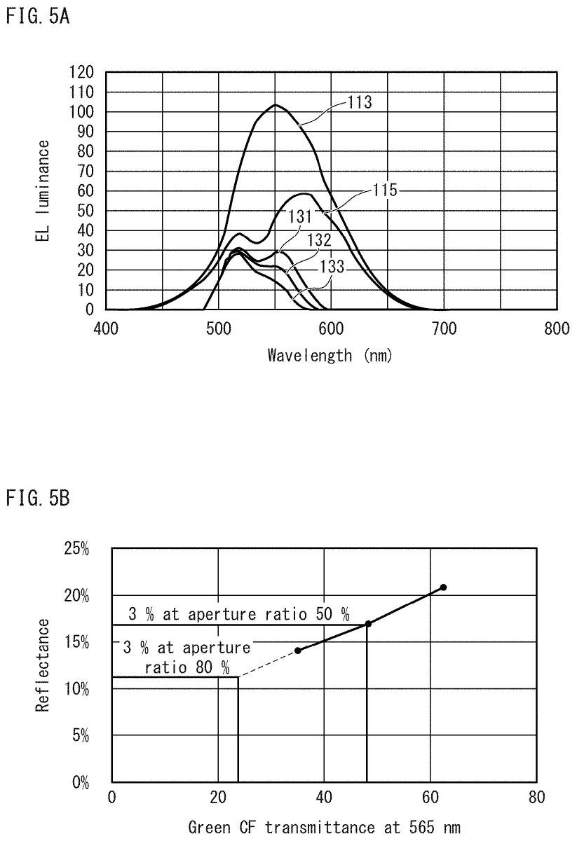

FIG. 5A illustrates reflected light spectra, in which a spectrum 131 corresponds to the Reference Example, a spectrum 132 corresponds to Embodiment 1, and a spectrum 133 corresponds to Embodiment 2. As above, the spectrum 113 illustrates the Y value of the CIE color matching function, the spectrum 115 illustrates reflected light in the absence of a color filter. As illustrated in FIG. 5A, in the spectrum 131 there are two peaks, one around 520 nm, which is the extraction wavelength of the optical resonator of the organic EL element 1(G), and the other is around 555 nm, which is the peak wavelength of the Y value in the CIE color matching function. That is, the reflected light includes light having a peak wavelength of 550 nm to 570 nm, and therefore the reflected light reduces color purity of the sub pixel 2(G). On the other hand, for Embodiment 1 (132) and Embodiment 2 (133), a peak exists around 520 nm, which is the extraction wavelength of the optical resonator of the organic EL element 1(G), but no peak can be confirmed around 555 nm, which is the peak wavelength of the Y value in the CIE color matching function. That is, a component in reflected light having a wavelength from 550 nm to 570 nm can be suppressed, and therefore a situation where color purity of the sub pixel 2(G) is decreased by reflected light can be suppressed. In order to sufficiently increase luminance of the sub pixel 2(G), transmittance of the color filter at about 520 nm, which is the extraction wavelength of the optical resonator of the organic EL element 1(G), is preferably at least 70%.

### (3.4) Relationship Between Reflectance and Aperture Ratio

FIG. 5B illustrates a relationship between light reflectance of the color filter 43(G) and light reflectance of the sub pixel 2(G). As illustrated in FIG. 5B, when light transmittance of the color filter 43(G) at a wavelength of 565 nm is 50%, light reflectance of the sub pixel 2(G) is about 17%. Here, assuming that reflectance values for the other sub pixels 2(R), 2(B) are the same, if the aperture ratio of the sub pixel 2(G) is 50%, reflectance of the organic EL display panel 100 will be 3%. Considering quality of a display panel, sufficient image quality can be obtained as long as reflectance is 3% or less, and therefore if an aperture ratio is 50%, transmittance of light having a wavelength of 565 nm in the color filter 43(G) is preferably 50% or less. If an aperture ratio of a sub pixel is 80%, reflectance of the sub pixel 2(G) needs to be about 12% or less, so that transmittance of light having a wavelength of 565 nm in the color filter 43(G) is preferably 24% or less.

### 4. Review

As described above, according to the display panel pertaining to an aspect of the present disclosure, in a green light emitting element, efficiency of extracting light as well as emission intensity and color purity of a desired wavelength can be improved by an optical resonator structure formed between the pixel electrodes and the counter electrode. Further, the color filter (G) has a structure in which a wavelength having a transmittance of 50% or less is in a wavelength range from 545 nm to 565 nm. That is, by setting transmittance of light of the color filter (G) around the wavelength of 555 nm to 50% or less, the reflectance of light around the wavelength of 555 nm is sufficiently reduced, and therefore a reduction in color purity caused by reflected light can be suppressed. Accordingly, it is possible to improve efficiency of a light emitting element by improving light extraction efficiency and lowering drive voltage, to extend life of the light emitting element and improve color purity. Further, reflectance can be reduced without using a black matrix, and therefore aperture ratio can be easily improved, and efficiency and life of the light emitting element can be further extended by reducing drive voltage.

### 5. Display Panel Manufacturing Method

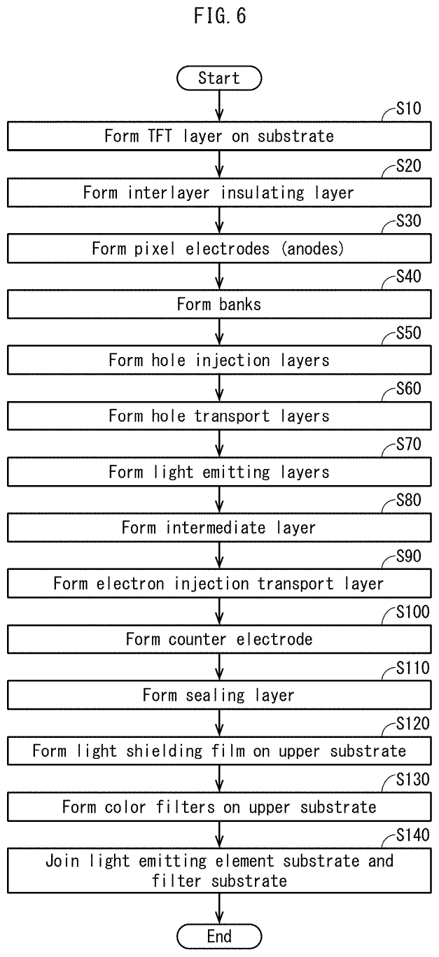

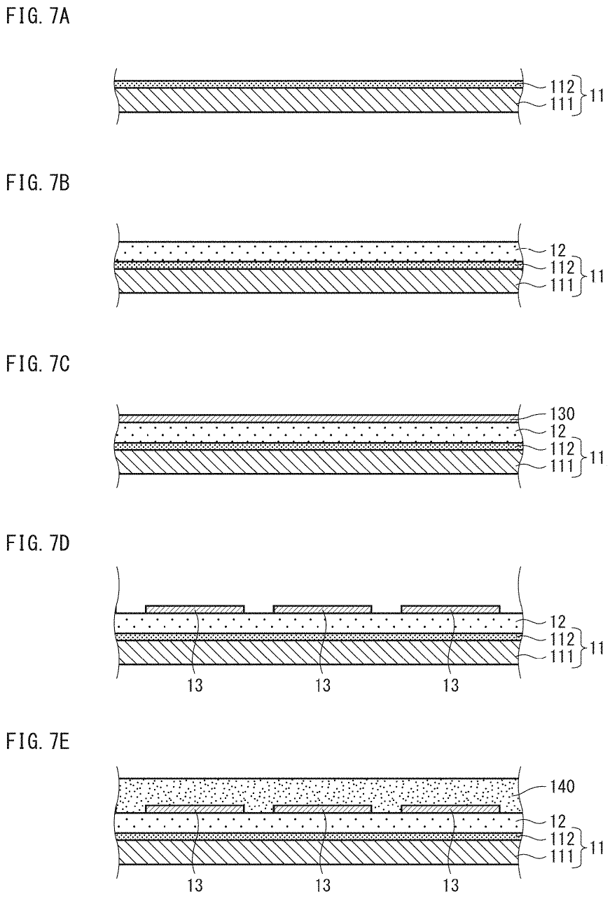

A method of manufacturing a display panel is described below with reference to the drawings. FIG. 6 is a flowchart illustrating a display panel manufacturing process. FIGS. 7A, 7B, 7C, 7D, 7E, 8A, 8B, 8C, 8D, 9A, 9B, 9C, 9D, 10A, 10B, 10C, 10D are schematic cross section diagrams illustrating states in each process of manufacturing the display panel.

### (1) Preparing Substrate 11

First, as illustrated in FIG. 7A, the TFT layer 112 is formed on the base 111 to form the substrate 11 (step S10). The TFT layer 112 can be formed by a known TP1 manufacturing method.

### (2) Forming Interlayer Insulating Layer 12

Next, as illustrated in FIG. 7B, the interlayer insulating layer 12 is formed on the substrate 11 (step S20). The interlayer insulating layer 12 can be laminated by using a plasma chemical vapor deposition (CVD) method, a sputtering method, or the like.

Next, a dry etching method is performed on the interlayer insulating layer 12 at locations above source electrodes of the TFT layer to form contact holes. The contact holes are formed so that bottoms of the contact holes expose top surfaces of the source electrodes.

Next, connection electrode layers are formed along inner walls of the contact holes. A portion of each of the connection electrode layers is disposed on the interlayer insulating layer 12. In forming the connection electrode layers, for example, a sputtering method can be used, and after forming a metal film, patterning is performed using a photolithography method and a wet etching method.

### (3) Forming Pixel Electrodes 13

Next, as illustrated in FIG. 7C, a pixel electrode material layer 130 is formed on the interlayer insulating layer 12. The pixel electrode material layer 130 can be formed by, for example, a vacuum vapor deposition method, a sputtering method, or the like.

Next, as illustrated in FIG. 7D, the pixel electrode material layer 130 is patterned by etching to form the pixel electrodes 13 partitioned into sub pixels (step S30).

### (4) Forming Banks 14

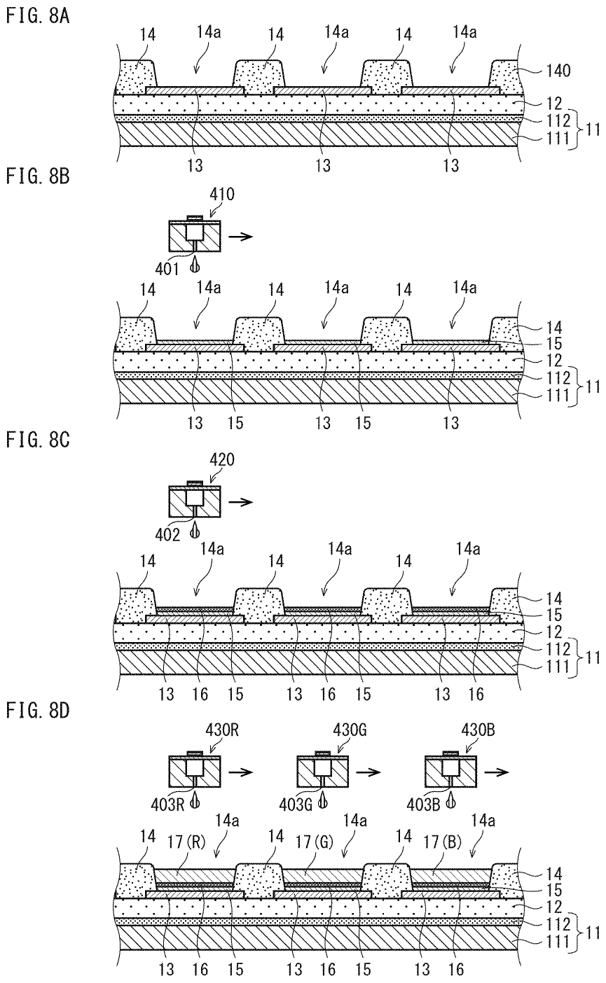

Next, as illustrated in FIG. 7E, a bank material layer 140 is formed by applying a bank layer resin that is a material of the banks 14 onto the pixel electrodes 13 and the interlayer insulating layer 12. The bank material layer 140 is formed by uniform application of a solution of phenol resin that is the bank layer resin dissolved in a solvent (for example, a mixed solution of ethyl lactate and γ-Butyrolactone (GBL)) by using a spin coating method or the like. Then the banks 14 are formed by pattern exposure and development performed on the bank material layer 140 (FIG. 8A) and baking the banks 14 (step S40). As a result, the apertures 14a are defined, which are areas for forming the light emitting layers 17. The banks 14 are baked, for example, at a temperature in a range from 150° C. to 210° C. for 60 minutes.

Further, in forming the banks 14, surfaces of the banks 14 may be further surface-treated with a defined alkaline solution, water, an organic solvent, or the like, or subjected to plasma treated. This is done to adjust a contact angle of the banks 14 with respect to the ink (solution) applied to the apertures 14a, or to impart water repellency to the surfaces.

### (5) Forming Hole Injection Layers 15

Next, as illustrated in FIG. 8B, ink containing the constituent material of the hole injection layers 15 is ejected from nozzles 401 of an inkjet head 410 into the apertures 14a defined by the banks 14 to be applied onto the pixel electrodes 13 in the apertures 14a, then dried (baked) to form the hole injection layers 15 (step S50).

Film formation of the hole injection layers 15 is not limited to ink application, and the hole injection layers 15 may be formed by a method such as vapor deposition. Further, when the hole injection layers 15 are formed by vapor deposition or sputtering, a process may be used in which after forming the pixel electrode material layer 130 in step S30, a hole injection material layer made of material of the hole injection layers 15 is formed on the pixel electrode material layer 130, then the pixel electrode material layer 130 and the hole injection material layer are patterned together in the same patterning process to form laminated structures of the pixel electrodes 13 and the hole injection layers 15.

### (6) Forming Hole Transport Layers 16

Next, as illustrated in FIG. 8C, ink containing the constituent material of the hole transport layers 16 is ejected from nozzles 402 of an inkjet head 420 into the apertures 14a defined by the banks 14 to be applied onto the hole injection layers 15 in the apertures 14a, then dried (baked) to form the hole transport layers 16 (step S60).

Film formation of the hole transport layers 16 is not limited to ink application, and the hole transport layers 16 may be formed by a method such as vapor deposition. Further, if all film formation of the pixel electrodes 13, the hole injection layers 15, and the hole transport layers 16 is performed by vapor deposition or sputtering, each layer may be patterned by the same patterning step as described above.

### (7) Forming Light Emitting Layers 17

Next, as illustrated in FIG. 8D, ink containing constituent material of the light emitting layers 17 is ejected from nozzles 403R of an inkjet head 430R, nozzles 403G of an inkjet head 430G, or nozzles 403B of an inkjet head 430B, respectively, into the apertures 14a onto the hole transport layers 16, then dried (baked) to form the light emitting layers 17 (step S70).

### (8) Forming Intermediate Layer 18

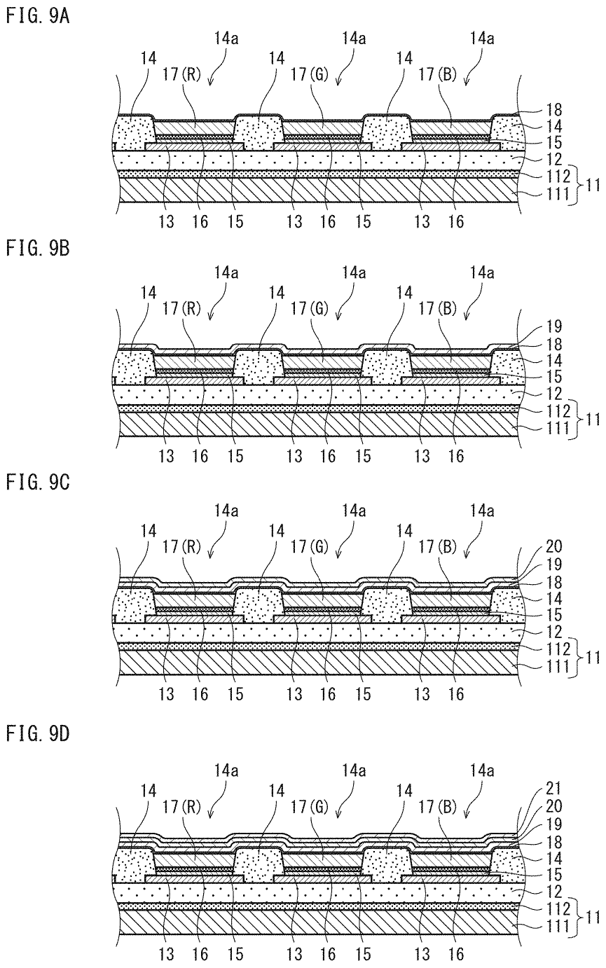

Next, as illustrated in FIG. 9A, an intermediate layer 18 is formed on the light emitting layers 17 and the banks 14 (step S80). The intermediate layer 18 is formed, for example, by film forming an alkali metal fluoride NaF across all sub pixels by a vacuum vapor deposition method.

### (9) Forming Electron Injection Transport Layer 19

Next, as illustrated in FIG. 9B, the electron injection transport layer 19 is formed on the intermediate layer 18 (step S90). The electron injection transport layer 19 is formed, for example, by film forming an electron-transporting organic material with ytterbium as a dopant across all sub pixels by a co-evaporation deposition method.

### (10) Forming Counter Electrode 20

Next, as illustrated in FIG. 9C, the counter electrode 20 is formed on the electron injection transport layer 19 (step S100). The counter electrode 20 is formed, for example, by film forming a metal material such as Ag or Al by a sputtering method or a vacuum deposition method.

### (11) Forming Sealing Layer 21

Next, as illustrated in FIG. 9D, the sealing layer 21 is formed (step S110). The sealing layer 21 can be formed by, for example, using SiON or SiN in a sputtering method or CVD method.

Completing this step completes the light emitting element substrate 30.

### (12) Forming Light Shielding Film 42

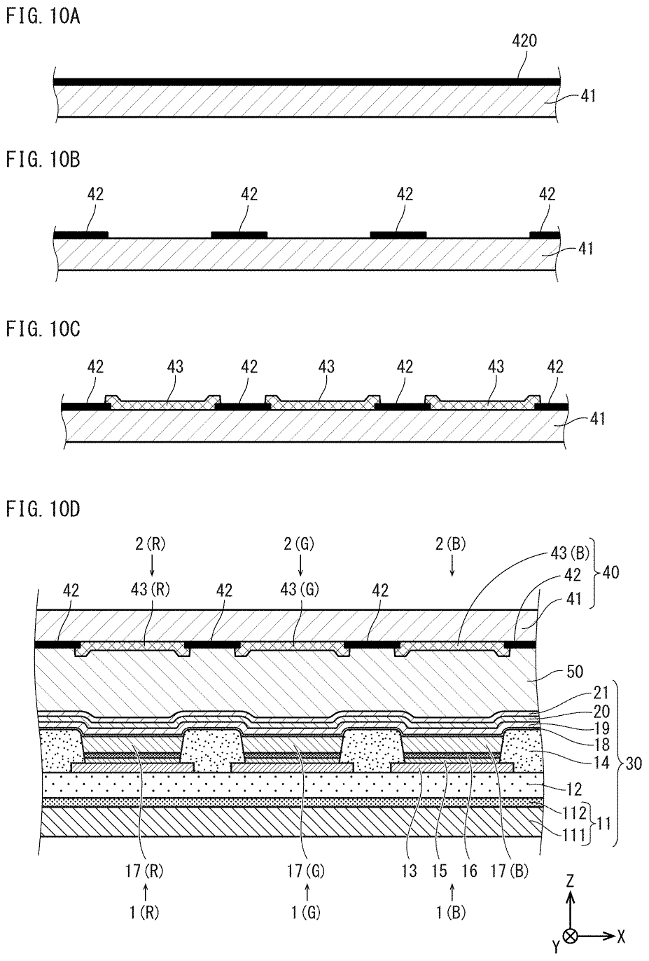

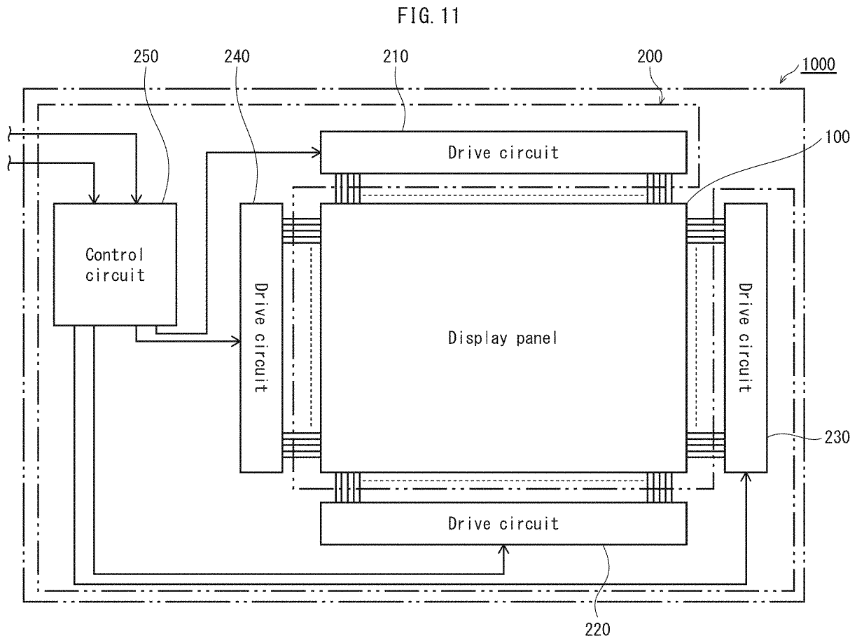

Next, as illustrated in FIG. 10A, material of the light shielding film 42 is applied onto the upper substrate 41 to form a light shielding material film 42. Next, the light shielding material film 42 is patterned and developed to form the light shielding film 42, then baked (FIG. 10B, step S120).

### (13) Forming Color Filters 43

Next, as illustrated in FIG. 10C, materials of the color filters 43 are separately applied to gaps of the light shielding film 42 and baked to form the color filters 43. The method of film formation of the color filters 43 is not limited to application and, for example, a color filter material layer may be formed as a solid film and the color filters 43 may be formed by pattern exposure and development.

### (14) Substrate Bonding

Finally, as illustrated in FIG. 10D, material of the bonding layer 50 is applied onto the sealing layer 21 of the light emitting element substrate 30, then the upper substrate is attached.

### 6. Overall Structure of Display Device

FIG. 11 is a schematic block diagram illustrating structure of a display device 1000 including the display panel 100. As illustrated in FIG. 11, the display device 1000 includes the display panel 100 and a drive controller 200 connected to the display panel 100. The drive controller 200 includes four drive circuits 210, 220, 230, 240 and a control circuit 250.

In the display device 1000, the arrangement of the driver controller 200 with respect to the display panel 100 is not limited to the illustrated example.

### «Effects»

The display panel pertaining to at least one embodiment of the present disclosure can suppress reflectance of light having a second wavelength in a pixel that includes a green light emitting layer. Therefore, in a pixel that includes a green light emitting layer, light having a first wavelength, which is the desired light, is efficiently emitted, and a decrease in color purity can be suppressed, where the decrease in color purity is caused by light having a second wavelength, which has high visibility characteristics and is included in external reflected light.

### Other Modifications of Embodiments

(1) According to at least one embodiment, the organic EL element 1 that is a light emitting element includes the hole injection layer 15, the hole transport layer 16, the intermediate layer 18, and the electron injection transport layer 19, but the light emitting element is not limited to this structure. The light emitting element may omit one or more of these layers, or may have other functional layers. For example, the intermediate layer 18 may be omitted, and an electron transport layer may be provided instead of the intermediate layer 18 or between the intermediate layer 18 and the light emitting layer 17.

Further, methods for producing each functional layer are merely examples. Other examples include that the light emitting layers 17 may be formed by a vapor deposition method, or the color filters 43 may be formed by a printing method.

(2) According to at least one embodiment, the display panel includes three types of light emitting elements that emit R, G, and B light, respectively, but as long as one type of light emitting element is a green light emitting element there may be one other type of light emitting element, or three or more types. Here, types of light emitting element indicates variation among light emitting elements, and even if light emission color is the same, types can be considered different if light emitting layer or functional layer film thicknesses are different. Further, arrangement of light emitting elements is not limited to the arrangement RGBRGB . . . . For example, an arrangement RGBBGRRGB . . . may be used, and an auxiliary electrode layer or other non-light emitting area may be provided between light emitting elements.

Further, according to at least one embodiment, the intermediate layer 18, the electron injection transport layer 19, and the counter electrode 20 are foinied as films common to all sub pixels, but film thicknesses may be different for each light emitting element.

(3) According to at least one embodiment, in the organic EL element 1, an optical resonator structure is formed from the interface between the pixel electrodes 13 and the hole injection layers 15 to the interface between the counter electrode 20 and the electron injection transport layer 19. However, a color filter 43 side of the optical resonator structure is not limited to the interface between the counter electrode 20 and the electron injection transport layer 19 and may be, for example, an interface between the counter electrode 20 and the sealing layer 21. Further, for example, an optical adjustment layer may be provided between the counter electrode 20 and the sealing layer 21, and the color filter 43 side of the optical resonator may be an interface between the counter electrode 20 and the optical adjustment layer, or a plurality of optical adjustment layers may be provided and the color filter 43 side of the optical resonator may be an interface between two adjacent optical adjustment layers.

(4) According to at least one embodiment, transmittance of the color filter 43(G) is set so that transmittance of light having a wavelength of about 555 nm (light having a wavelength selected from a range from 545 nm to 565 nm) is 50% or less. However, the sub pixel 2 may include the organic EL element 1(G), a conventional color filter, and a reflection suppression filter having a light transmittance of 50% or less for light having a wavelength of about 555 nm. Here, as the reflection suppression filter, an edge filter that does not allow light having a wavelength of 555 nm or more to pass through may be used, for example. The reflection suppression filter may, for example, be provided in the color filter substrate 40 by being laminated on the color filter 43(G), or may be provided in the light emitting element substrate 30 on the counter electrode 20 of the organic EL element 1(G).

(5) According to at least one embodiment, the pixel electrodes are anodes and the counter electrode is a cathode, but the pixel electrodes may be cathodes and the counter electrode may be an anode.

(6) Although the display panel and the display device according to the present disclosure have been described based on embodiments and modifications, the present invention is not limited to the above embodiments and modifications. Embodiments obtained by applying various modifications conceived by a person skilled in the art to embodiments or modifications described above, as well as embodiments obtained by any combination of components and function of embodiments or modifications that do not depart from the spirit of the present invention are also included in the scope of the present invention.

What is claimed is:

1. A display panel including pixels each including a self-luminous element and a color filter, the display panel comprising:
a green light emitting element among the self-luminous elements, wherein
the green light emitting element has an optical resonator structure in which a light transmissive metal thin film electrode, a green light emitting layer, and a light reflective electrode are disposed in this order with the light transmissive metal thin film electrode closest to one of the color filters corresponding to the green light emitting element, in order to enhance light intensity of a first wavelength, and
the one of the color filters has a light transmittance of 50% or less for light having a second wavelength that is longer than the first wavelength and has a higher visibility characteristic as a green color component than the first wavelength.

2. The display panel according to claim 1, wherein in the International Commission on Illumination (CIE) color matching functions, a Y value corresponding to the second wavelength is larger than a Y value corresponding to the first wavelength.

3. The display panel according to claim 1, wherein the first wavelength is 530 nm or less and the second wavelength is 565 nm.

4. The display panel according to claim 1, wherein the first wavelength is 530 nm or less and the second wavelength is 555 nm.

5. The display panel according to claim 1, wherein the first wavelength is 530 nm or less and the second wavelength is 545 nm.

6. The display panel according to claim 1, wherein the one of the color filters has a light transmittance of 70% or more for light having the first wavelength.

7. The display panel according to claim 1, wherein an aperture ratio of a pixel including the green light emitting element is 50% or more.

8. A display panel including pixels each including a self-luminous element and a first color filter, the display panel comprising:
a green light emitting element among the self-luminous elements, wherein
the green light emitting element has an optical resonator structure in which a light transmissive metal thin film electrode, a green light emitting layer, and a light reflective electrode are disposed in this order with the light transmissive metal thin film electrode closest to one of the first color filters corresponding to the green light emitting element, in order to enhance light intensity of a first wavelength, and
a pixel including the green light emitting element is further provided with a second color filter that has a light transmittance of 50% or less for light having a second wavelength that is longer than the first wavelength and has a higher visibility characteristic as a green color component than the first wavelength.

9. A display device including the display panel of claim 1 and a drive circuit.

10. A display panel manufacturing method comprising:
forming light reflective electrodes on a substrate;
forming a light emitting layer above each of the light reflective electrodes;
forming a light transmissive metal thin film electrode above the light emitting layers to form an optical resonator structure; and
forming a color filter above each of the light emitting layers, above the light transmissive metal thin film electrode, wherein
in forming the light emitting layers, at least one light emitting layer is a green light emitting layer, and
in forming the color filters, when a peak wavelength of the optical resonator structure is a first wavelength, light transmittance of a color filter above the green light emitting layer is 50% or less for light having a second wavelength that is longer than the first wavelength and has a higher visibility characteristic as a green color component than the first wavelength.
